(19) United States
(12) Patent Application Publication
(10) Pub. No.: US 2003/0075672 A1
(43) Pub. Date: Apr. 24, 2003

(54) Method and apparatus for coupling optical fiber with photodetectors

(76) Inventor: Yet-Zen Liu, Westlake Village, CA (US)

Correspondence Address: TEJINDER SINGH, NEWPORT LAW GROUP, 5001 BIRCH STREET, NEWPORT BEACH, CA, 92660, US

(21) Appl. No.: 10/032,946

(22) Filed: Oct. 19, 2001

(51) Int. Cl. H01L 31/00

(52) U.S. Cl. 250/214.1

(57) ABSTRACT

A method and apparatus is provided for aligning a photodetector, such that the photodetector is placed at an inclined angle on an inclined mounting device and incident light enters the photodetector absorption layer at an angle.

### BACKGROUND OF THE INVENTION

1. Field of the Invention

The present invention relates to semiconductor photodetectors and, more particularly to coupling optical fiber with the photodetectors.

2. Background

Semiconductor photodetectors (hereinafter referred as “photodetectors” or “photodetector”) are extensively used in high bandwidth fiber optics networks. FIG. 1A shows a top level block diagram of a typical fiber optics network 100, which includes a transmitter 100A that receives an electrical input (not shown) and converts it to an optical output 100B using a laser diode (not shown). Optical signal 100B is transmitted via optical fiber (not shown) and is received by optical amplifier 100C. Optical amplifier 100C amplifies optical signal 100B and the amplified signal 100D is transmitted to photodetector 100F, via filter 100E.

Typically, photodetectors detect light when incident light from optical fiber is absorbed by an absorption layer. The absorbed photons create primary electron-hole pairs and generate electric current. The photodetector is generally connected to a trans-impedance amplifier that receives the output current from the photodetector and converts it into voltage.

FIG. 1B shows a cross-sectional view of a typical photodetector 100F. Turning in detail to FIG. 1B, a laminated structure is sequentially formed by a n-type cladding layer 104, an absorption layer 103, a p-type cladding layer 102 and an ohmic contact layer 101, on a semiconductor substrate 105. Electrodes (not shown) are mounted on ohmic contact layer 101 and on the back surface of layer 105. If a reverse voltage is applied between layers 102 and 104, incident light (not shown) guided to absorption layer 103 is converted into a photoelectric signal.

Conventional photodetectors have thin absorption layers to minimize carrier transit time, which enables photodetectors to respond to high-speed optical signals. However, a thin absorption layer reduces the overall quantum efficiency of the photodetector because less light is absorbed.

Conventional techniques direct incident light to absorption layer 103 at an angle. This increases the effective absorption layer 103's thickness and improves the overall quantum efficiency of the photodetector because more incident light is absorbed when light enters absorption layer 103 at an angle than if it were to enter in a direction perpendicular to absorption layer 103 (FIG. 1B).

FIG. 1C illustrates a cross-sectional view of a conventional system for increasing absorption while maintaining an acceptable absorption layer thickness. Semiconductor wafer 110 of a photodetector with wave guide 109 includes a reflecting edge 107 that is anistropically (an expensive and tedious process) etched. Incident light 106 from optical fiber (not shown) is reflected off reflecting surface 107 and directed to absorption layer 108, at an angle θ. Absorption layer 108 absorbs more light since incident light 106 enters absorption layer 108 at an angle.

One disadvantage of the foregoing system is that reflecting layer 107 is fabricated by using complex and expensive anisotropic etching because it involves alteration of the wafer 110's structure. Anisotropic etching increases the cost of wafer manufacturing and is burdensome.

Therefore, there is a need for a method and apparatus for increasing absorption of light in a photodetector without complex and expensive processing.

### SUMMARY OF THE INVENTION

There is provided in accordance with one aspect of the present invention an inclined mounting block so that incident light enters the absorption layer of a photodetector at an angle. The photodetector is placed on an inclined edge of the mounting block and incident light enters the absorption layer at an angle, which increases the overall absorption of light and that improves the quantum efficiency of the photodetector.

In accordance with another aspect of the present invention, the inclined mounting block is simple to fabricate and complex anisotropic etching for forming a reflecting edge with a desired angle to direct incident light to the photodetector is not required.

This brief summary has been provided so that the nature of the invention may be understood quickly. A more complete understanding of the invention can be obtained by reference to the following detailed description of the preferred embodiments thereof in connection with the attached drawings.

### BRIEF DESCRIPTION OF THE DRAWINGS

FIG. 1A described above, is an illustration of a block diagram of a typical fiber optics network.

FIG. 1B described above, is an illustration of a cross-sectional view of a typical photodetector.

FIG. 1C described above, illustrates an example of a cross-sectional view of a conventional system for directing incident light to a photodetector.

FIG. 2A illustrates a block diagram of a system for aligning a photodetector, according to an embodiment of the present system.

FIG. 2B graphically illustrates the relationship between incident light entry angle θ and incline angle a, as shown in FIG. 2A.

FIG. 2C illustrates a front view of a photodetector of FIG. 2A coupled to a trans-impedance amplifier.

FIG. 3A illustrates a process flow diagram for aligning a photodetector according to an embodiment of the present invention.

FIG. 3B illustrates a front view of a photodetector aligned, according to another embodiment of the present invention.

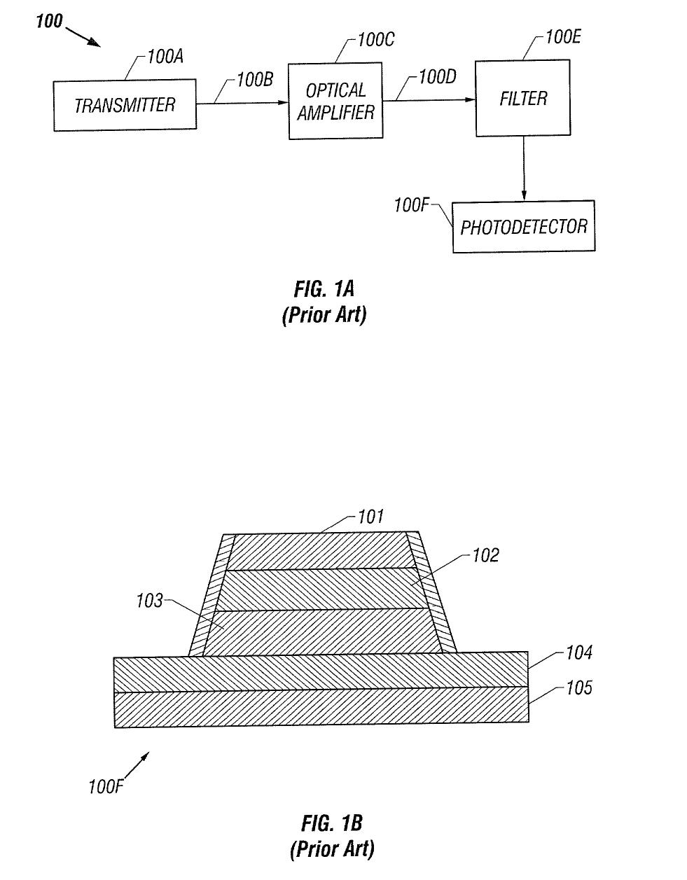

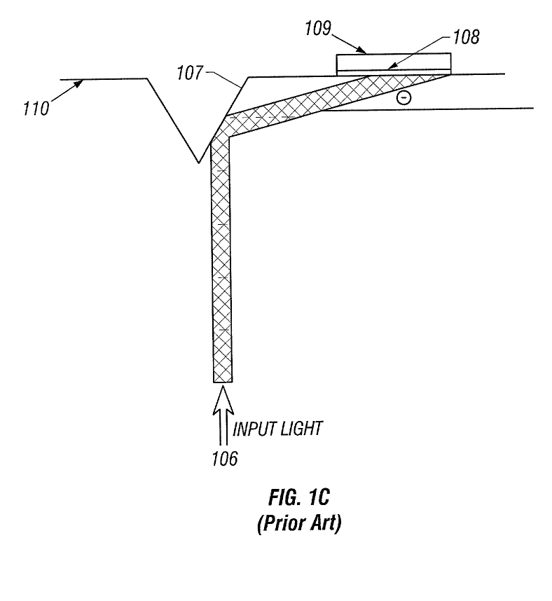

Features appearing in multiple figures with the same reference numeral are the same unless otherwise indicated.

### DETAILED DESCRIPTION

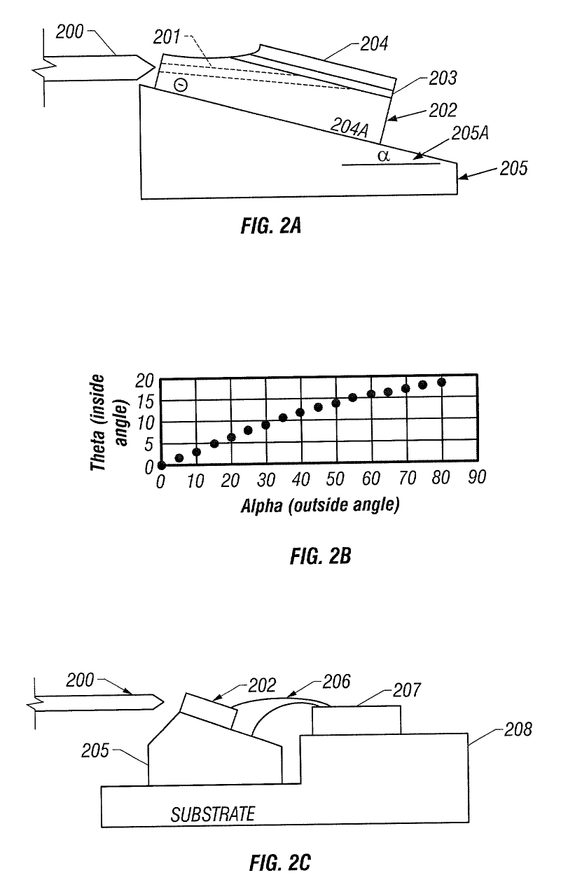

FIGS. 2A and 2C illustrate the location of a photodetector according to an embodiment of the present invention such that input light enters the photodetector absorption layer at an angle. The photodetector is placed on an inclined edge of a mounting block such that incoming input light enters the absorption layer of the photodetector at an angle, thereby more light is absorbed by the absorption layer.

Referring to FIG. 2A in detail, photodetector 202 is located on mounting block 205. Photodetector 202 includes waveguide 204 and absorption layer 203. Mounting block 205 includes an inclined edge 205A, for placing photodetector 202. Inclined edge 205A is inclined at an angle α. Incident light (not shown) passes through optical fiber 200 and optical path 201 and then enters absorption layer 203 at an angle θ, and hence, increases the absorption of light by absorption layer 203.

The relationship between the incident light entry angle θ and incline angle a is given by:

sin (θ)=n⁻¹ sin (α)

where n is the refractive index of InP layer 204A of photodetector 202. FIG. 2B graphically illustrates the relationship between the incident light entry angle θ and incline angle α.

Referring now to FIG. 2C in detail, photodetector 202 is located on mounting block 205 to receive incident light via optical fiber 200. Photodetector 202 is coupled to a trans-impedance amplifier 207 by connectors 206, where trans-impedance amplifier 207 receives output (not shown) from photodetector 202 and converts the photo current output (not shown) into voltage. Mounting block 205 is placed on substrate 208.

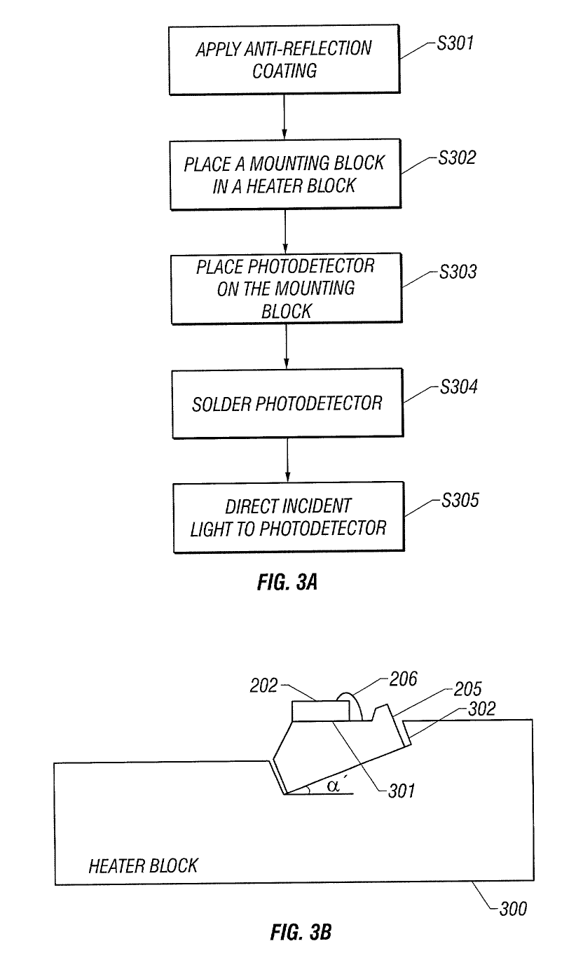

In yet another aspect of the present invention a process is provided for increasing absorption of light by absorption layer 203 without increasing absorption layer 203 thickness, or expensive anisotropic etching. Referring to FIG. 3A, the process comprises of: applying anti-reflection coating on the photodetector edge directly facing incoming light; placing the mounting block on a blockheater with a recess; soldering the photodetector to the inclined edge of the mounting block; and directing the incoming incident light such that light is absorbed by the absorption layer at an angle.

Turning in detail to FIG. 3A, in step S301, apply anti-reflection coating on the photodetector edge directly facing incident light through optical fiber 200 (FIG. 2C). The anti-reflection coating minimizes loss of optical power due to reflection.

In step S302, place mounting block 205 in a heater block. FIG. 3B shows mounting block 205 placed in heater block 300. Heater block 300 includes a recess 302 for receiving mounting block 300. The mounting surface for recess 302 is inclined at angle α′ (recess angle) such that photodetector 202 is horizontal.

In step S303, place photodetector on mounting block 205. As shown in FIG. 3B because of the inclination of recess 302, photodetector 202's mounting surface is horizontal.

In Step S304, solder photodetector 202 to inclined edge 205A (FIG. 2A). Conductive epoxy or other similar adhesives may also be used to place photodetector 202 on inclined edge 205A. It is noteworthy that the invention is not limited to soldering or conducting epoxy, any other coupling means may be used to couple photodetector 202 to inclined edge 205A.

In step S305, direct incident light to the photodetector, such that incident light enters the photodetector at an angle. Incident light travels through optical fiber 200 and optical path 201 and is absorbed by absorption layer 203 at angle θ (FIG. 2A). The angle (θ) at which incident light is received by absorption layer 203 is given by:

sin (θ)=n⁻¹ sin (α)

where n is the refractive index of InP layer 204A and α is the inclined angle of mounting block 205 (FIG. 2A).

The foregoing increases the absorption of light by absorption layer 203 and improves the quantum efficiency of photodetector 202.

Another aspect of the present invention is that mounting block 205 is simple to fabricate and the process does not require complex and expensive anisotropic etching for fabricating a special reflecting edge on the semiconductor wafer.

While the present invention is described above with respect to what is currently considered its preferred embodiments, it is to be understood that the invention is not limited to that described above. To the contrary, the invention is intended to cover various modifications and equivalent arrangements within the spirit and scope of the appended claims.

What is claimed is:

1. An apparatus for directing incident light to a photodetector, comprising:
a mounting device for placing the photodetector at an inclined angle to receive the incident light.

2. The apparatus of claim 1, further comprising:
an absorption layer in the photodetector that absorbs the incident light.

3. The apparatus of claim 2, wherein the incident light enters the absorption layer at an angle.

4. The apparatus of claim 1, wherein the mounting device includes an edge at an inclined angle for receiving the photodetector.

5. The apparatus of claim 4, wherein the inclined angle is equal to the product of refractive index value of an InP layer in the photodetector and the angle in which incident light enters the absorption layer.

6. A method for directing incident light to a photodetector, comprising:
placing the photodetector on an inclined edge of an inclined mounting block; and
receiving incident light, wherein the incident light is received by the photodetector at an angle.

7. The method of claim 6, wherein the incident light is absorbed by an absorption layer in the photodetector.

8. The method of claim 6, wherein the inclined angle is equal to the product of a refractive index value of an InP layer in the photodetector and the angle in which incident light enters the absorption layer.

9. The method of claim 6, wherein the photodetector is soldered to the inclined mounting block.

10. The method of claim 6, wherein the photodetector is coupled to the mounting block by conducting epoxy.

11. A system for directing incident light to a photodetector, comprising:
means for placing the photodetector at an inclined angle to receive the incident light.

12. The system of claim 11, wherein the incident light enters an absorption layer of the photodetector at an angle.

13. A method for coupling a photodetector to a mounting block, comprising:
placing the mounting block in a heater block; and
placing the photodetector on the mounting block.

14. The method of claim 13, wherein the heater block includes a recess edge such that the photodetector is horizontal with respect to a mounting surface.

15. The method of claim 13, further comprising:
soldering the photodetector to the mounting block.

16. The method of claim 13, further comprising:
coupling the photodetector with the mounting block by conducting epoxy.

17. A heater block for locating a photodetector on a mounting block, comprising:
a recess edge for receiving the photodetector mounted on the mounting block.

18. The heater block of claim 17, the recess edge is inclined such that the photodetector is horizontal with respect to a mounting surface of the mounting block.
